(19) United States
(12) Patent Application Publication
(10) Pub. No.: US 2025/0156611 A1
(43) Pub. Date: May 15, 2025

(54) MACHINE LEARNING DELUGE

(71) Applicant: Autodesk, Inc., San Francisco, CA (US)

(72) Inventors: Sam Robert Jamieson, London (GB); Jason Lao, Markham (CA); Marco Antonio Rodrigues Andrade, Mississauga (CA); Siavash Hakim Elahi, Long Beach, CA (US); Vishnu Prathish, Cambridge (CA); Gerald Brown, Didcot (GB); Samer Muhandes, Sutton (GB); Maciek Tytus Rybczynski, Waterloo (CA)

(73) Assignee: Autodesk, Inc., San Francisco, CA (US)

(21) Appl. No.: 18/944,784

(22) Filed: Nov. 12, 2024

Related U.S. Application Data
(60) Provisional application No. 63/598,226, filed on Nov. 13, 2023.

(51) Int. Cl. G06F 30/28; G06F 30/27; G06N 3/08

(52) U.S. Cl. CPC G06F 30/28; G06F 30/27; G06N 3/08

(57) ABSTRACT

A method and system provide for generating a stormwater overland flow map. Simulation inputs (ground surface data) and simulation outputs (stormwater overland flow maps) are obtained from a deluge simulation model that simulates where water will channel and accumulate on a surface. A convolutional neural network (CNN) is trained to approximate the simulation outputs of the deluge simulation model. The CNN is a sequence of CNN models that each represent a time step and each CNN model in the sequence takes CNN output from a previous CNN model as its input. The CNN output is a video output and a visual representation of stormwater overland flow over time. A new input is a first format is obtained. A collection of custom objects representing points of a grid are stored and includes z-values of points on the surface and stormwater controls. The grid is populated and then processed in/by the CNN.

### CROSS-REFERENCE TO RELATED APPLICATIONS

This application claims the benefit under 35 U.S.C. Section 119 (e) of the following co-pending and commonly-assigned U.S. provisional patent application(s), which is/are incorporated by reference herein:

U.S. Provisional Patent Application Ser. No. 63/598,226, filed on Nov. 13, 2023, with inventor(s) Sam Jamieson, Jason Lao, Marco Antonio Rodrigues Andrade, Siavash Hakim Elahi, Vishnu Prathish, Gerald Brown, Samer Muhandes, and Maciek Tytus Rybezynski, entitled “Machine Learning Deluge”, Attorney Docket No. 30566.0618USP1.

### BACKGROUND OF THE INVENTION

### 1. Field of the Invention

The present invention relates generally to water flow prediction, and in particular, to a method, apparatus, system, and article of manufacture for using machine learning (MI) to predict water flow.

### 2. Description of the Related Art

There is a need to determine where water will be ponding to help designers choose the best location for storage structures and Storm Water Controls (SWCs). Flood maps are commonly established, examined and analyzed as part of such a determination. Further, prior art systems require lengthy traditional deluge simulations that solve equations to establish the flood maps. In this regard, a deluge simulation is a simulation of a large downpour of rain, often a flood that allows a site to be assessed by supplying an amount of rainfall to the surface to establish likely channeling and ponding. Such a deluge simulation applies water to a surface and simulates where the water channels and accumulates (i.e., to determine flooding hotspots and avoid them when constructing a building, office, school, etc.).

Prior art/traditional deluge tools depend on meshing a ground model and then solving equations for each mesh element and analyzing where the water is going to accumulate and where it will be channeled. This process tends to be computationally expensive as the equations are being solved for each mesh element and for each time step. For example, for a ten (10) hectare site, prior art systems may end up solving more than 144 million equations during a 24 hour simulation. Such prior art systems are computationally intensive and associated with long simulations times. Accordingly, what is needed is a system and method to establish flood maps in an efficient and accurate manner without lengthy simulations.

### SUMMARY OF THE INVENTION

Embodiments of the invention provide an innovative machine learning (ML) deluge service that is tailored to provide unprecedented speed, stability, and adaptability in the assessment of flood maps when applying an amount of rainfall to the surface (ground model) to establish locations where water will be ponding. In other words, embodiments of the invention use ML to build a surrogate model and obtain deluge flood maps without having to solve equations. Such capabilities help designers choose the best location for storage structures and Storm Water Controls (SWCs). Without lengthy simulations, embodiments of the invention provide users with flood maps so the drainage design becomes more intelligent, responsive, and efficient.

The ML deluge of embodiments of the invention bypasses the need to solve equations as the algorithm has been trained on circa 10,000 different simulations (e.g., surfaces and associated flood maps from public domain sources) and it has learnt the flood map associated with many different topographies. Therefore, by spotting patterns, embodiments of the invention manage to establish the flood map associated with the water depth applied on the surface with a speed between 16× to 25× the traditional deluge speed.

Use of the ML deluge tool of embodiments of the invention enables users to get instant feedback in real time whenever they move a pond or a swale thereby providing interactivity and real time experience. In other words, embodiments of the invention fundamentally transform simulation from step-wise/command driven simulations to an interactive experience with real-time feedback thereby setting the stage to expand applications to more complex urban scenes for flood forecasting.

### BRIEF DESCRIPTION OF THE DRAWINGS

Referring now to the drawings in which like reference numbers represent corresponding parts throughout:

FIG. 1 illustrates the overall design workflow including data engineering and model building in accordance with one or more embodiments of the invention;

FIG. 2A illustrates a convolutional neural network (CNN) as a predictive model utilized in accordance with one or more embodiments of the invention;

FIG. 2B illustrates the sequence of three selected CNN models for a third sample in accordance with one or more embodiments of the invention;

FIG. 3 illustrates end-to-end system latency in accordance with one or more embodiments of the invention;

FIGS. 4 and 5 illustrate a graphical user interface for initially activating a deluge tool in accordance with one or more embodiments of the invention;

FIG. 6 illustrates a graphical user interface indicating the building of a mesh in accordance with one or more embodiments of the invention;

FIG. 7 illustrates a graphical user interface indicating the progress of the mesh generation in accordance with one or more embodiments of the invention;

FIG. 8 illustrates a graphical user interface showing an initial pond placement in accordance with one or more embodiments of the invention;

FIG. 9 illustrates a graphical user interface showing pond movement in accordance with one or more embodiments of the invention;

FIGS. 10-11 illustrate graphical user interfaces with further pond movement in accordance with one or more embodiments of the invention;

FIG. 12 illustrates the logical flow for generating a stormwater overland flow map in accordance with one or more embodiments of the invention;

FIG. 13 is an exemplary hardware and software environment used to implement one or more embodiments of the invention; and

FIG. 14 schematically illustrates a typical distributed/cloud-based computer system in accordance with one or more embodiments of the invention.

### DETAILED DESCRIPTION OF THE INVENTION

In the following description, reference is made to the accompanying drawings which form a part hereof, and which is shown, by way of illustration, several embodiments of the present invention. It is understood that other embodiments may be utilized and structural changes may be made without departing from the scope of the present invention.

### Overview

Embodiments of the invention utilize ML to build a surrogate model and obtain deluge flood maps without having solve equations. The ML model is trained on simulations (surfaces and associated flood maps) from public domain sources. Subsequent to training the ML model, a surface is passed to the ML algorithm, and the ML outputs flood maps that are similar to prior art traditional deluge flood maps. Embodiments of the invention further provide for interactive drainage where users can place/move ponds and swales on a surface. In response, the updated surface is reprocessed by the ML algorithm and the flood map is dynamically updated in real time. In other words, every time a pond/swale is moved, immediate feedback in the flood map is provided. In addition, embodiments of the invention provide for interactive building where customers/users can place/move building objects on a surface, and the updated surface is reprocessed by the ML algorithm and the flood map is updated live (dynamically in real time) to identify where not to place buildings. In other words, embodiments provide immediate feedback while buildings/floodwalls/other objects are moved around.

### Design Workflow

One may implement the surrogate modeling (also referred to as ML) as a cloud service with tricky input requirements and a nonconventional output. Existing prior art systems (e.g., INFODRAINAGE™) may be implemented as high-end drainage design software that provides two different ways to see a two-dimensional (2D) representation of the pooling of water on a surface (referred to as a deluge). A deluge essentially shows what would happen with water dumped across a surface and is fairly quick but does not take into account any stormwater controls such as ponds the user adds to their design, and 2D analysis, which takes into account the specified rainfall and all manholes/ponds etc. but takes significantly longer to calculate. Embodiments of the invention utilize surrogate modelling that is able to use the service to calculate the distribution of water on a surface considering ponds (and some other stormwater controls) with a calculation time as quick as or faster than a prior art deluge calculation.

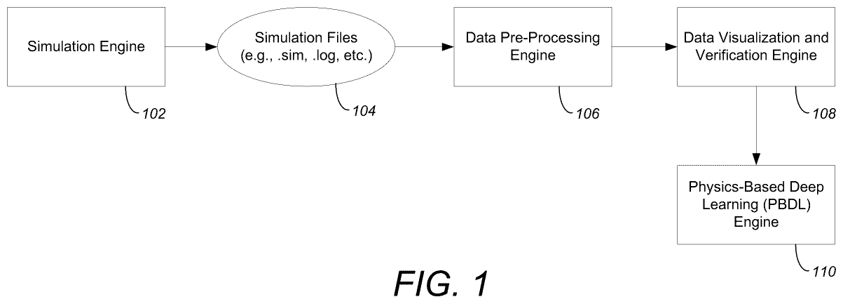

FIG. 1 illustrates the overall design workflow including data engineering and model building in accordance with one or more embodiments of the invention. The various aspects of the workflow are described in more detail below.

### Unusual Formats

Deluge systems are used to passing around various sorts of hydraulic and rainfall data, but machine learning tools often care about things slightly differently to what deluge might care about for a proper rigorous analysis. Embodiments of the invention provide a surrogate modelling service 102 that takes an input of a 500×500 ASCII grid, and outputs a bitmap file (i.e., simulation files 104 such as .sim, .log, etc.). The surface data is not held as an ASCII grid, and the objects holding deluge results are a bit more complicated than a bitmap file. Any desktop product reaching out to a machine learning powered service is likely to have to consider how to quickly convert to and from these inputs and outputs.

### Pre-Processing and Pre-Pre-Processing

To convert from surface data to an ASCII grid, it became clear very quickly that a faster way to navigate the network of triangles and vertices that make up our surface data was needed. Embodiments of the invention decided on an R-Tree implementation so that for each point in the 500×500 ASCII grid, the system could very quickly find the Z value from the surface. However, one may also need to determine whether any stormwater controls are relevant. At the same time, as much as an R-Tree implementation speeds up pre-processing, it is undesirable to have to perform this kind of calculation on every 250,000 points every time a user moves a pond before sending anything up to the surrogate modelling service. Accordingly, the problem becomes one of implementing a connection to a particularly demanding cloud service's API (application programming interface) in an established desktop product.

In view of the above, embodiments of the invention may hold a collection of very lightweight custom objects representing the points in the ASCII grid in memory, with both the relevant Z value for the surface, and the relevant Z value of any stormwater control on top of it. This way one would only have to navigate the surface on load, and with the help of a GUID dictionary, relevant grid nodes may be updated whenever a stormwater control is updated. Such embodiments were lightweight enough in memory and spread the CPU load across the usage of the program, so that the ASCII grid is essentially already populated by the time the call to the surrogate modelling service is needed.

Further, to provide such capabilities, the data pre-processing engine 106 deletes the unnecessary files, removes corrupted files, compresses the data, and uploads the data into storage (e.g., an S3 bucket or other cloud storage container for objects stored in a simple storage service [S3]).

### Post-Processing and the Value of Limits

Once pre-processed (at pre-processing engine 106), data visualization and verification engine 108 visualizes the ground model and depth, checks the number of realizations, and verifies the propagation of water depth over time.

Further to the above, it may be noted that systems may be accustomed to receiving much more explicit and detailed data from calculations than a single bitmap image provides. To figure out a way of converting this data (and quickly!), embodiments of the invention may request a limitation on the surrogate modelling service. That limitation was that the maximum level of water on a surface to be displayed by the bitmap file be capped at 1 metre. This is reasonable as users often want to update their model if water of this depth (or greater) was pooling anywhere they were not intending for it to be. Importantly, this allows embodiments of the invention to have a very quick conversion back from the bitmap colouring—with values of 0 signifying a depth of 0 m and values of 255 signifying a depth of 1 m. This quick conversion back into depth data then allows embodiments of the invention to offer users a similar flexibility to prior art deluge results in terms of display settings.

In other words, one or more embodiments of the invention cap the max depth thereby enabling the ability to convert back and forth between ASCII at different points quickly and efficiently.

### Surrogate Modelling

Returning to FIG. 1, once the data has been processed (at step 106) and verified (at step 108), the physics-based deep learning (PBDL) engine 110 performs the surrogate/ML modeling. The purpose of a surrogate model (or ML model) is to approximate the results of more complex modelling or simulations, while accepting a higher degree of error but with computation speed as the advantage.

Embodiments of the invention (via PBDL 110) leverage the inputs and outputs of a full simulation to train a Convolutional Neural Network to approximate the results of the simulation but provide results much faster than if running the full simulation. This would allow users to quickly iterate through designs and get an idea of the impact of their changes. In addition, embodiments of the invention are able to provide dynamic results showing the evolution of water flow over time (15 timesteps to be more precise).

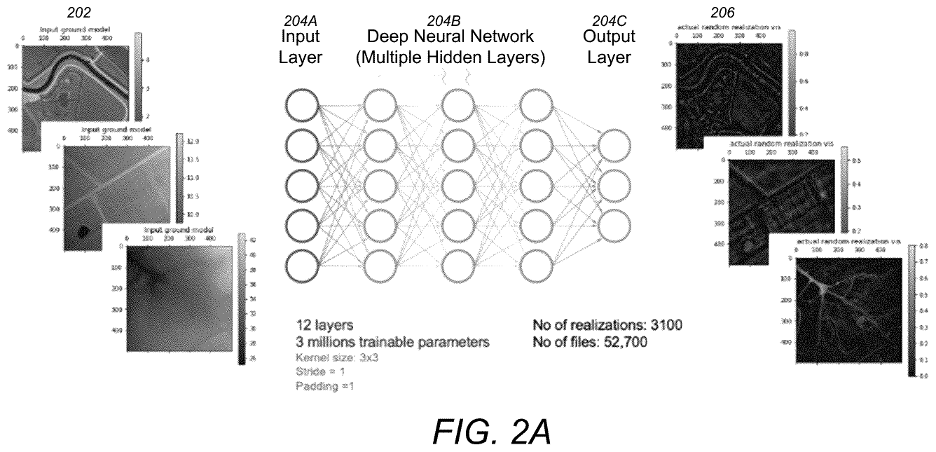

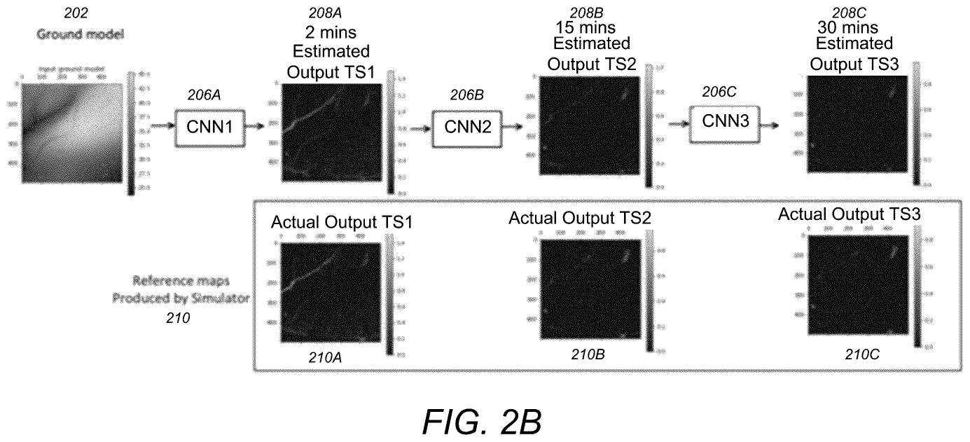

FIG. 2A illustrates a convolutional neural network (CNN) as a predictive model utilized in accordance with one or more embodiments of the invention. As illustrated, ground models 202 were used as input (i.e., into input layers 204A). Such ground models may consist of LIDAR data from ground topography or other publicly available ground model data (e.g., from government sources). In addition, suitable parameters were specified. Specifically, the CNN 204 includes the input layer 204A, the deep neural network 204B (which includes multiple hidden layers) and output layer 204C (collectively 204A-204C are referred to as the CNN 204). The deep neural network 204B generates the output layer 204C which includes actual random realization visualizations. A illustrated, the DNN includes 12 different layers, 3 million trainable parameters, a kernel size of 3×3, a stride of 1, and padding of 1. Using such a configuration, 3100 realizations/realization visualizations 206 and 52,700 files were generated (by the DNN 204B).

One may note that the traditional simulation process involves solving a set of partial differential equations and discretizing them in both time (t) and space (x, y). However, the input data/ground models 202 utilized in embodiments of the invention, the spatial discretization has already been captured in the ground image 202, which serves as the input to the Convolutional Neural Network (CNN) 204. To incorporate the time discretization and utilize it in a surrogate model, embodiments of the invention redesigned the architecture to include a sequence of CNN models 204.

Each model 204 in the sequence takes the output of the previous model as its input. This allows the models 204 to learn and predict the evolution of stormwater overland flow over time. As used herein, stormwater overland flow refers to the rain landing on a surface and following the land's topography to find low spots and form flooding hotspots. In other words, only the first model receives the ground image 202 and predicts the stormwater overland flow map for the next time step (t1). Then, this predicted stormwater overland flow at t1 is used as input to predict the stormwater overland flow at t2, and so on.

During training, this sequence of CNN models 204 learns to observe and predict the changes in the water map over time. Later, when deployed, the sequence of models can generate a video output 206 representing the evolution of the stormwater overland flow.

FIG. 2B illustrates the sequence of three selected CNN models 206A-206C for a third sample in accordance with one or more embodiments of the invention. As illustrated the ground model 202 is processed through sequential CNNs 206A-206C generating estimated outputs 208A-208C at different timesteps (i.e., TS1 of 2 mins, TS2 of 15 mins, and TS3 of 30 mins). Reference maps 210 produced by the actual simulator at the timestamps are illustrated for reference/comparison purposes (i.e., actual output TS1 210A, actual output TS2 210B, and actual output TS3 210C). As illustrated the estimated outputs 208A-208C generated by the CNNs 206 are fairly close to the actual outputs 210 produced by the simulator.

As a result of incorporating the sequence of CNN models 204 into the architecture of embodiments of the invention, several improvements were achieved. Firstly, the accuracy of the surrogate model has been enhanced. By allowing each model in the sequence to build upon the predictions of the previous model, embodiments are able to capture the evolving dynamics of the stormwater overland flow more effectively. Additionally, this approach enables the generation of a video output instead of a single image. By leveraging the predictions made by each model in the sequence, a visual representation of the stormwater overland flow over time can be created. This video output provides a more comprehensive and dynamic understanding of the system behavior, allowing for better analysis and interpretation of the results.

### Inference Time Improvement

In determining the CNN 204 to utilize, one challenge was to provide a low latency service that could perform the prediction (or inference) from the CNN and respond to the desktop client app in a reasonable time. The development process was done in two versions. The first version had a response time target of 5-7 seconds, and leveraged AWS (AMAZON WEB SERVICES) LAMBDAS as the primary compute unit for the surrogate service. This first version managed to get close to the target response time, but with a high degree of variation. Through the development of this first version, it was learned that the biggest bottleneck was the size of the file being transferred from the client application to the backend service. With full precision, uncompressed files, response times of around 13 seconds (files were approximately 5 Mb in size) were achieved. By reducing precision (to 2 or 3 decimal digits) and compressing the input files, embodiments of the invention were able to lower the response times to around 6.3 seconds. The conclusion was that once the file was within the AWS network and being processed by a backend application, the inference and post-processing times were acceptable. The true unknown was the transfer time, which can be heavily affected by the user's network connection. At this point in the development process, it was determined that response times between 6 and 13 seconds would not make up for a good user experience, since the goal was to be more dynamic and allow for fast iteration through designs.

Further to the above, while developing the first version of the application, it was noticed that much higher speeds of inference could be achieved (in this case, just the time the CNN 204 takes to make a forward pass) by leveraging better hardware in AWS. Testing with GPU accelerated hardware, embodiments of the invention were able to get inference in under 1 second, which is much faster than the approximate 4 seconds that was achieved by performing inference within the AWS LAMBDA. For a second version, therefore, embodiments of the invention leveraged AWS SAGEMAKER to get access to better, GPU-accelerated hardware. The new architecture then used AWS LAMBDAS for the pre- and post-processing of the inputs, with an AWS SAGEMAKER realtime endpoint performing the loading of the model and inference. After benchmarking tests, embodiments of the invention settled on a ml.g4dn.xlarge instance, since it provided an average inference time of 0.74 seconds for the relatively low cost—other instances performed slightly better but at much higher costs. The resulting response times from using SAGEMAKER and GPU-accelerated instances was significant: 5.6 seconds for full precision, uncompressed inputs and 2.1 seconds for 2- or 3-decimal precision, compressed inputs. With these response times, one could be more confident that the surrogate model could be used in real-time to provide dynamic results to final users. Table 1 illustrates these estimated response times within the AWS network (e.g., of ˜1.2 s)

TABLE 1

| | | | 2-decimal | 2-decimal |
|---|---|---|---|---|
| | Full Precision | Full Precision | Precision | Precision |
| | Uncompressed | Compressed | Uncompressed | Compressed |
| Version | (~5 MB) | (~900 Kb) | (~1.5 MB) | (~350 Kb) |
| V1 | 13 s | 6.9 s | 7.6 s | 6.3 s |
| V2 | 5.6 s | 3.0 s | 2.7 s | 2.1 s |

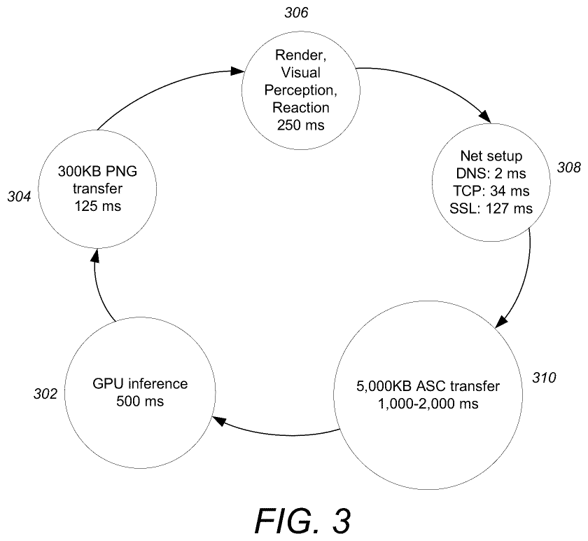

Embodiments of the invention may also further reduce latency. FIG. 3 illustrates end-to-end system latency in accordance with one or more embodiments of the invention. As illustrated, the processing/computing times are approximately 500 ms for GPU inference 302, 125 ms for a 300 KB PNG transfer 304, 250 ms for a render, visual perception, reaction 306, net setup 308 with 2 ms for DNS, 34 ms for TCP, and 127 ms for SSL, and 1,000-2000 ms for a 5,000 KB ASC transfer 310. As can be seen, system latency is dominated by the data transfer of the input representation 310. Embodiments of the invention provide for:
lower precision, compressed matrix input (up to 100× smaller);
Rasterizing in AWS, and “stamping” a base triangle mesh with user design choices; and
Streaming over a longer-lasting connection to eliminate network setup overhead-if multiple related request/responses are expected for a particular client workflow.

### Additional/Alternative Usage Improvements

Speed—in embodiments of the invention, the process may take longer than desired. Embodiments of the invention may greatly increase the speed by reducing the pre-processing time incurred (e.g., by INFO DRAINAGE), and by doing some of this pre-processing in advance of when it is needed. From a usage perspective the change is that, as soon as a surface is loaded, the values necessary to populate the ascii grid consumed by the service are kept in memory and these values are updated as changes are made.

SWC Stamping—in embodiments of the invention, values passed to the service may be entirely dictated by a loaded surface, and are not affected by anything the user can put on the plan. Additional embodiments of the invention may alter this so that Pond and Swale stormwater controls are effectively ‘stamped’ into the grid passed to the surface, so that they affect the results. Such stamps may include rectangular, circular, and freeform outlines for both straight sided and sloped stormwater controls.

Iterations—Maintain Results/Iterative functionality—in embodiments of the invention, the user may be required to select an Interactive Deluge option each time they wish to get a surrogate model. Alternative embodiments may function such that after the first time the user has selected an Interactive Deluge option, the surrogate model will be updated any time a change is made to either the surface or a stormwater control. The new surrogate model will not be displayed instantly, but very quickly, and rather than blocking the application with a progress form to make these requests, the same functionality present for a 1D analysis may be utilized when a “Maintain Results” option is switched on. That is, assuming inputs are valid, the user may simply see the progress in the bottom left/taskbar portion of a software application (e.g., INFODRAINAGE), and the plan will be updated with the new surrogate model image on completion (assuming the display setting for it is on of course).

Legend/Display setting updates-Embodiments of the invention may only display the image returned from the surrogate modelling service. Alternative embodiments may instead evaluate the bitmap returned and provide a legend and display settings similar to existing 2D display settings to allow the user to select colors and opacity for various thresholds. Note that the maximum depth of water on top of the surface may be capped at 1 m.

### Graphical User Interface (GUI)

The deluge tool of embodiments of the invention allows the site to be assessed by applying an amount of rainfall to the surface to establish likely channeling and ponding. This will provide key information to establish where the best locations for storage structures and also key locations to avoid when designing buildings and evacuation routes. Users are able to either use simulation-based deluge or ML based deluge and they will get a flood map indicating the likely channeling and ponding.

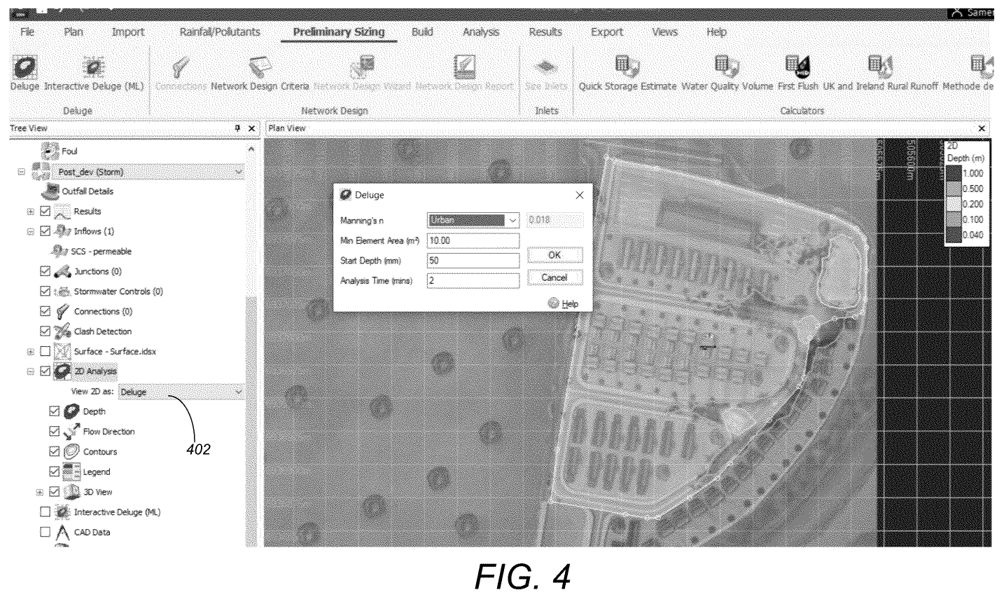

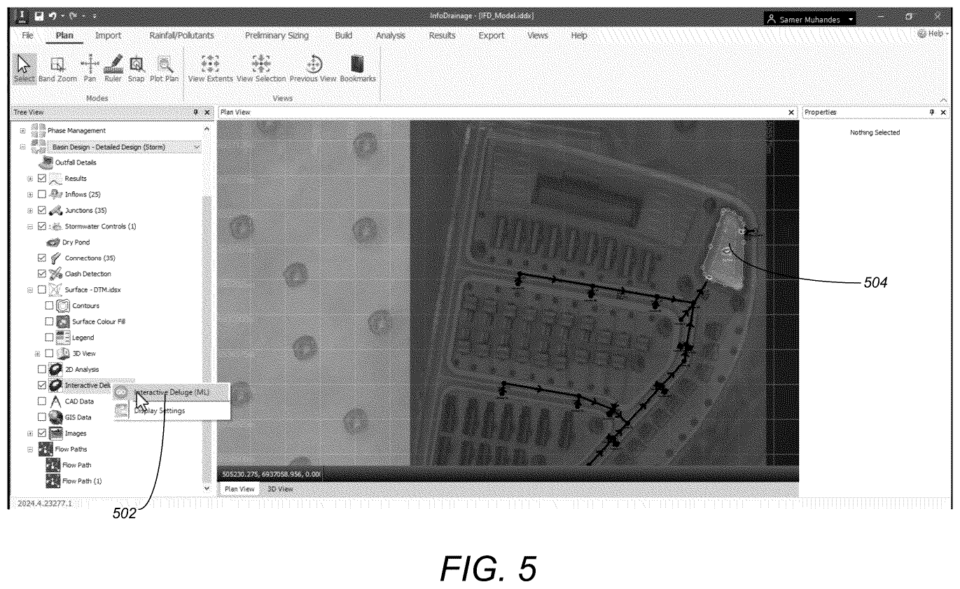

FIGS. 4-11 are screenshots of the graphical user interface for the deluge tool in accordance with one or more embodiments of the invention. FIGS. 4 and 5 illustrate the initial activation of the deluge tool. To run a deluge, a surface is loaded, and then the user clicks on “Deluge” 402, or a different embodiment, “Interactive Deluge (ML)” 502, or simply from the Preliminary Sizing ribbon, a deluge analysis can be run to retrieve the flood maps associated with a certain depth of water applied on the surface.

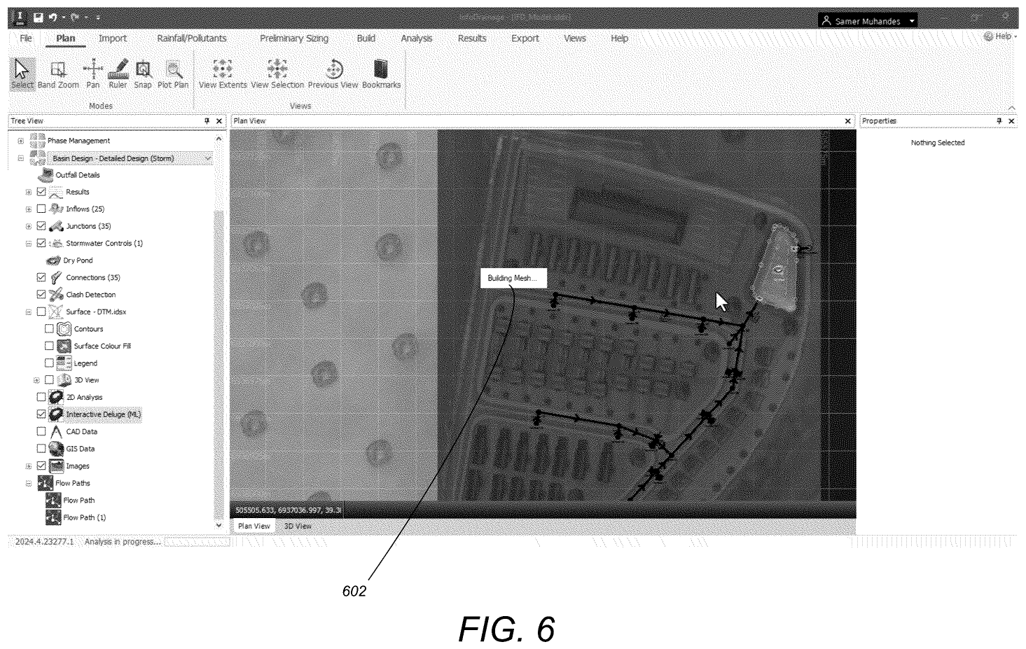

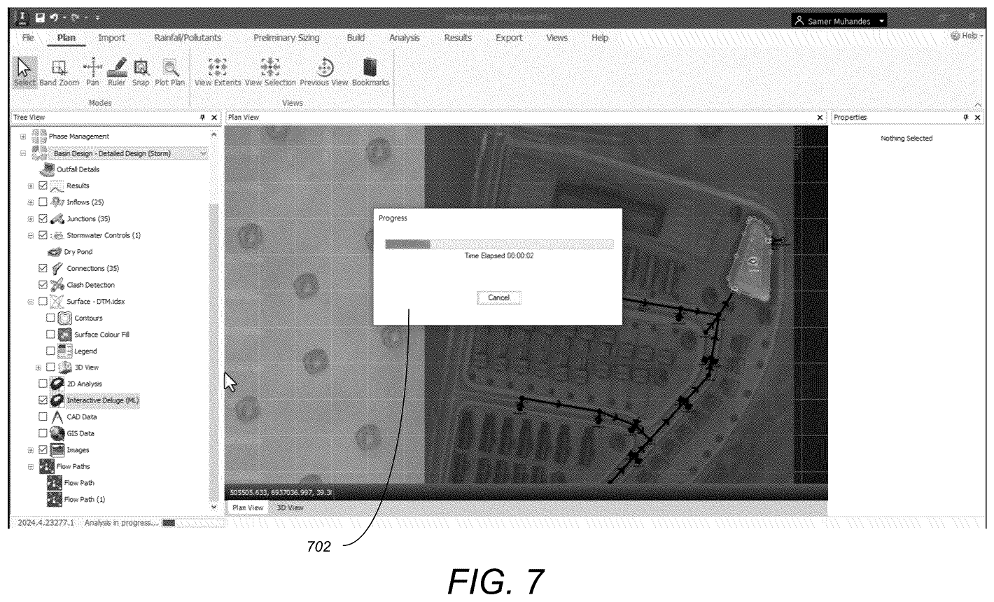

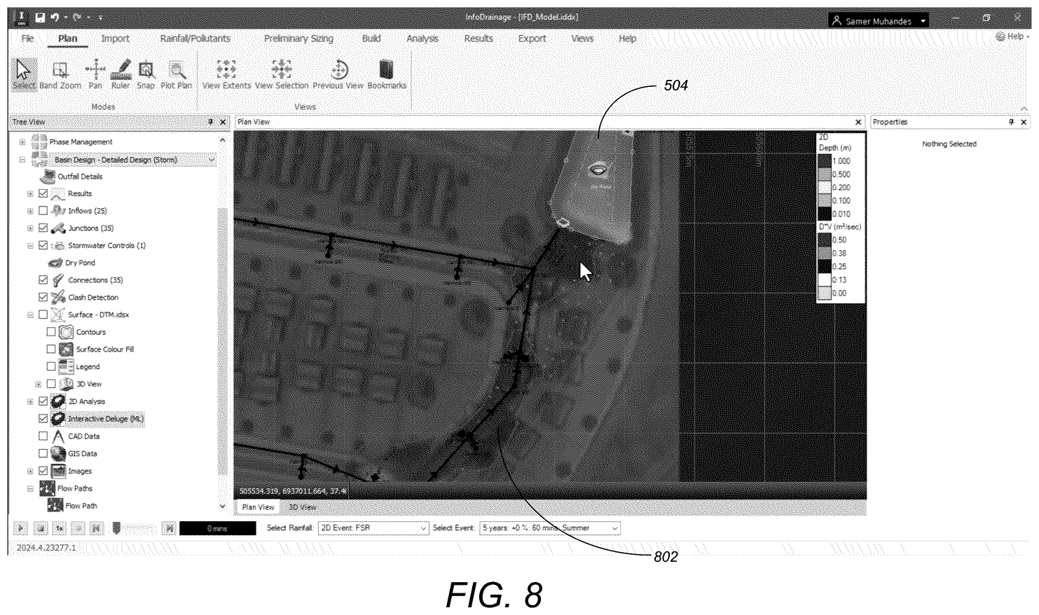

As illustrated in FIG. 6, once activated, the deluge tool indicates that the mesh is being built (see message 602). FIG. 7 then illustrates the progress of the mesh generation via status window 702. In FIG. 8, the pond 504 has been initially placed in the upper right corner of the site and one can see where the water accumulates (via shading/coloring 802).

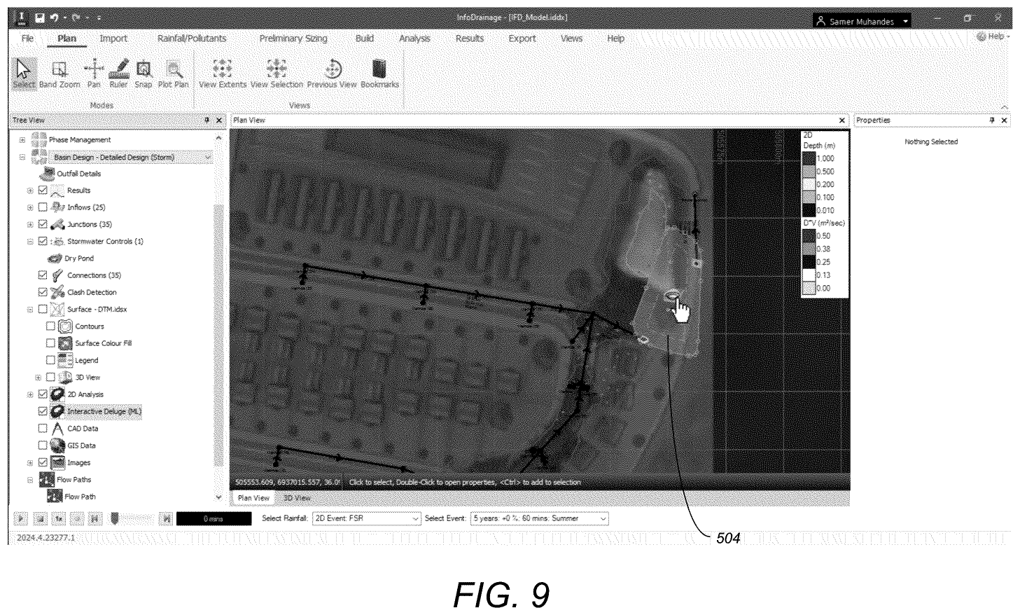

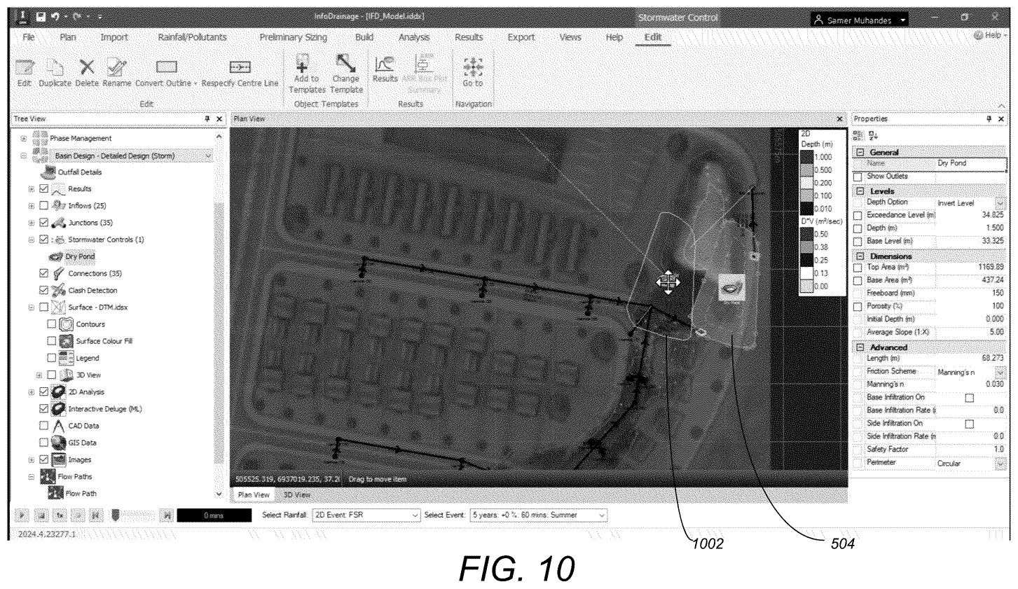

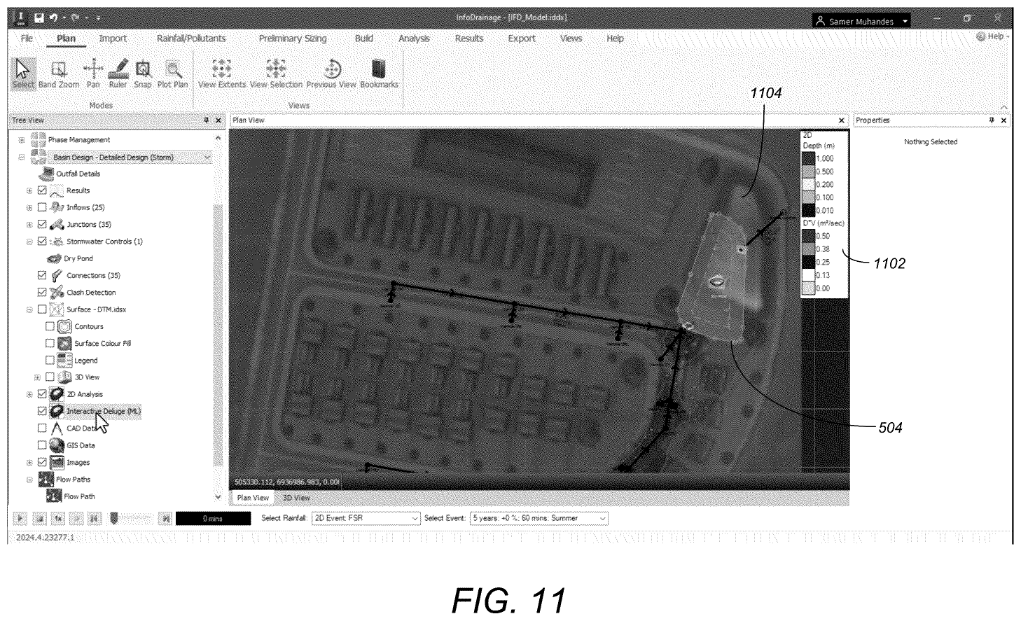

The user can then move the pond 504 where desired and retrieve instantaneous, dynamic, real-time feedback regarding the pond 504 placement. For example, as illustrated in FIG. 9, the user may move the pond 504 to the right and the flood map will be updated instantly to reflect the impact of the change. As illustrated in FIG. 10, the user can then move the pond 504 to the left (the outline 1002 captures where the user is attempting to move the pond 504 [via a mouse click and hold] before actually moving the pond (via mouse button release) (as illustrated in FIG. 11).

Once actually placed, the GUI (as illustrated in FIG. 111) will provide immediate feedback on the flood map as a result of moving the pond 504 to the left. Finally, the user may place the pond in the middle (e.g., of the accumulating water with the final placement location similar to that illustrated in FIGS. 4-8) to capture the overland flow—again with real-time dynamic updates to the flood map and a real-time experience.

In view of the above, with the help of the deluge tool, one can see where the water is expected to accumulate which would inform decisions related to locations of ponds, buildings and evacuation routes. As illustrated (e.g., via the depth map 1102 (reflecting the coloring/shading of the depths of the water accumulation 1104), the perfect location for the pond 504 would be the top right corner of the site.

### Logical Flow

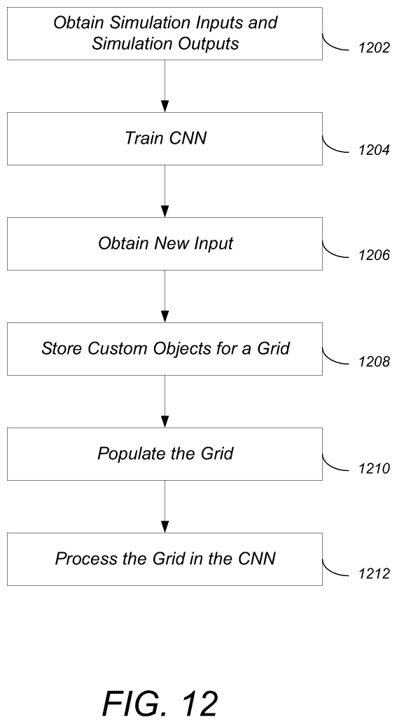

FIG. 12 illustrates the logical flow for generating a stormwater overland flow map in accordance with one or more embodiments of the invention.

At step 1202, simulation inputs and simulation outputs are obtained from a deluge simulation model. The deluge simulation model simulates where water will channel and accumulate on a surface. Further, the simulation inputs are ground surface data. In addition, each simulation output is a stormwater overland flow map.

At step 1204, a convolutional neural network (CNN) is trained to approximate the simulation outputs of the deluge simulation model. In this regard, the CNN is a sequence of CNN models where each CNN model in the sequence represents a time step. A first CNN model in the sequence receives new ground image data and predicts the stormwater overland flow map for a subsequent time step. Each subsequent CNN model in the sequence takes CNN output from a previous CNN model as its CNN input. An output of the CNN (i.e., a CNN output) is a video output that is a visual representation of stormwater overland flow over time.

In one or more embodiments, the CNN is a Bayesian CNN that estimates a map of standard deviations to address uncertainties in the deluge simulation model. In a Bayesian CNN, the model parameters are treated as random variables with prior distributions, P (A). During training, Bayesian inference is used to update these distributions based on the observed data P(B|A) and P(B), resulting in posterior distributions P(A|B) that reflect both the prior beliefs and the observed evidence. Specifically, the following equation/probabilities may be utilized to represent the Bayesian CNN:

$$P ( A \vert B ) = \frac{P ( B \vert A ) \times P ( A )}{P ( B )}$$

Where P(A|B) is the posterior, P(B|A) is the likelihood, P(A) is the prior, and P(B) is the evidence.

In one or more embodiments of the invention, the CNN is integrated with deep learning in real time to address uncertainties due to specific numerical methods utilized in the deluge simulation model. In additional embodiments, the CNN is processed in AMAZON WEB SERVICES using graphics processing unit (GPU) accelerated hardware.

At step 1206, a new input that consists of new ground surface data is obtained in a first format.

At step 1208, a collection of custom objects representing points of a grid is stored in memory. Each custom object is a first z-value of a point on the new ground surface data and a second z-value of a stormwater control on top of the new round surface data. Further, the grid may consist of an ASCII (American Standard Code for Information Interchange) grid.

At step 1210, the grid is populated using the collection of custom objects.

At step 1214, the grid is processed in/by the CNN to generate the CNN output. The output generation may include the display of the stormwater overland flow map.

In one or more embodiments, there may be a limit/cap on a maximum level of water on a surface to be displayed in the CNN output. In such embodiments, the CNN output may also include bitmap coloring that is converted to depth data based on bitmap color values.

Further to the above, in one or more embodiments of the invention, the obtaining the new input may include stamping a defined water collection area onto the new ground image data. Such a stamping may include interactively placing a polygonal shaped area onto the new ground image data. The grid is then repopulated based on the defined water collection area. Thereafter, the repopulated grid is reprocessed in the CNN to generate the CNN output. In this regard, the CNN output is generated and displayed in real time dynamically in response to the stamping. In one or more embodiments, such a stamping may consist of interactively moving the polygonal shaped area onto a different area of the new ground image data. As used herein, the defined water collection area may be is selected from a group consisting of a pond, a swale, and a channel (i.e., it can be a pond, swale, channel, or other area that collects water).

### Hardware Environment

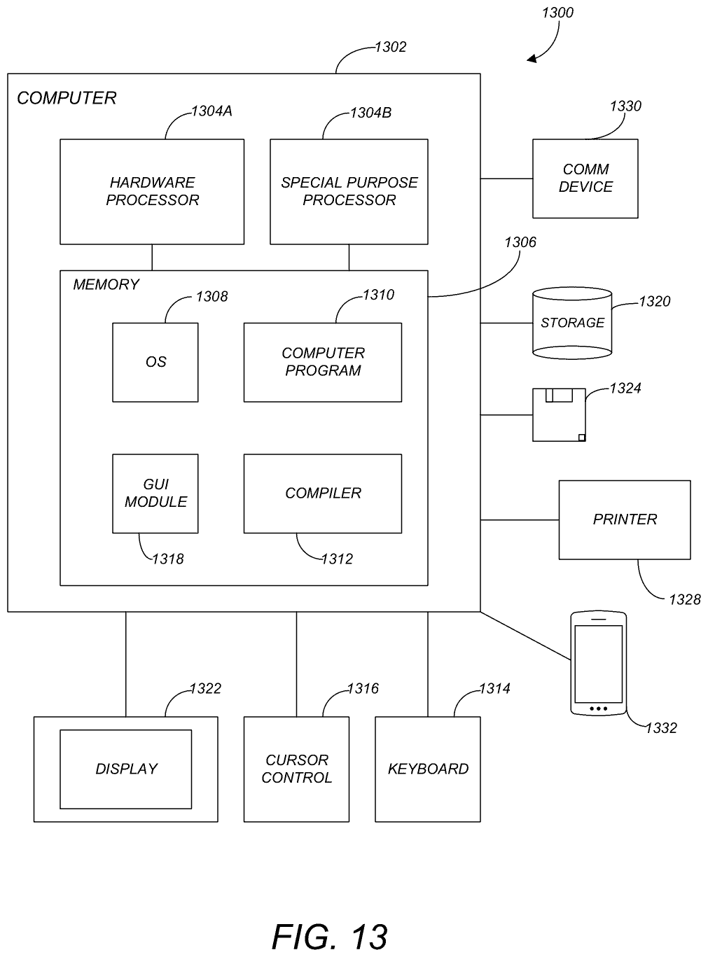

FIG. 13 is an exemplary hardware and software environment 1300 (referred to as a computer-implemented system and/or computer-implemented method) used to implement one or more embodiments of the invention. The hardware and software environment includes a computer 1302 and may include peripherals. Computer 1302 may be a user/client computer, server computer, or may be a database computer. The computer 1302 comprises a hardware processor 1304A and/or a special purpose hardware processor 1304B (hereinafter alternatively collectively referred to as processor 1304) and a memory 1306, such as random access memory (RAM). The computer 1302 may be coupled to, and/or integrated with, other devices, including input/output (I/O) devices such as a keyboard 1314, a cursor control device 1316 (e.g., a mouse, a pointing device, pen and tablet, touch screen, multi-touch device, etc.) and a printer 1328. In one or more embodiments, computer 1302 may be coupled to, or may comprise, a portable or media viewing/listening device 1332 (e.g., an MP3 player, IPOD, NOOK, portable digital video player, cellular device, personal digital assistant, etc.). In yet another embodiment, the computer 1302 may comprise a multi-touch device, mobile phone, gaming system, internet enabled television, television set top box, or other internet enabled device executing on various platforms and operating systems.

In one embodiment, the computer 1302 operates by the hardware processor 1304A performing instructions defined by the computer program 1310 (e.g., a computer-aided design [CAD] application) under control of an operating system 1308. The computer program 1310 and/or the operating system 1308 may be stored in the memory 1306 and may interface with the user and/or other devices to accept input and commands and, based on such input and commands and the instructions defined by the computer program 1310 and operating system 1308, to provide output and results.

Output/results may be presented on the display 1322 or provided to another device for presentation or further processing or action. In one embodiment, the display 1322 comprises a liquid crystal display (LCD) having a plurality of separately addressable liquid crystals. Alternatively, the display 1322 may comprise a light emitting diode (LED) display having clusters of red, green and blue diodes driven together to form full-color pixels. Each liquid crystal or pixel of the display 1322 changes to an opaque or translucent state to form a part of the image on the display in response to the data or information generated by the processor 1304 from the application of the instructions of the computer program 1310 and/or operating system 1308 to the input and commands. The image may be provided through a graphical user interface (GUI) module 1318. Although the GUI module 1318 is depicted as a separate module, the instructions performing the GUI functions can be resident or distributed in the operating system 1308, the computer program 1310, or implemented with special purpose memory and processors.

In one or more embodiments, the display 1322 is integrated with/into the computer 1302 and comprises a multi-touch device having a touch sensing surface (e.g., track pod or touch screen) with the ability to recognize the presence of two or more points of contact with the surface. Examples of multi-touch devices include mobile devices (e.g., IPHONE, NEXUS S, DROID devices, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 1302 according to the computer program 1310 instructions may be implemented in a special purpose processor 1304B. In this embodiment, some or all of the computer program 1310 instructions may be implemented via firmware instructions stored in a read only memory (ROM), a programmable read only memory (PROM) or flash memory within the special purpose processor 1304B or in memory 1306. The special purpose processor 1304B may also be hardwired through circuit design to perform some or all of the operations to implement the present invention. Further, the special purpose processor 1304B may be a hybrid processor, which includes dedicated circuitry for performing a subset of functions, and other circuits for performing more general functions such as responding to computer program 1310 instructions. In one embodiment, the special purpose processor 1304B is an application specific integrated circuit (ASIC).

The computer 1302 may also implement a compiler 1312 that allows an application or computer program 1310 written in a programming language such as C, C++, Assembly, SQL, PYTHON, PROLOG, MATLAB, RUBY, RAILS, HASKELL, or other language to be translated into processor 1304 readable code. Alternatively, the compiler 1312 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 1310 accesses and manipulates data accepted from I/O devices and stored in the memory 1306 of the computer 1302 using the relationships and logic that were generated using the compiler 1312.

The computer 1302 also optionally comprises an external communication device such as a modem, satellite link, Ethernet card, or other device for accepting input from, and providing output to, other computers 1302.

In one embodiment, instructions implementing the operating system 1308, the computer program 1310, and the compiler 1312 are tangibly embodied in a non-transitory computer-readable medium, e.g., data storage device 1320, which could include one or more fixed or removable data storage devices, such as a zip drive, floppy disc drive 1324, hard drive, CD-ROM drive, tape drive, etc. Further, the operating system 1308 and the computer program 1310 are comprised of computer program 1310 instructions which, when accessed, read and executed by the computer 1302, cause the computer 1302 to perform the steps necessary to implement and/or use the present invention or to load the program of instructions into a memory 1306, thus creating a special purpose data structure causing the computer 1302 to operate as a specially programmed computer executing the method steps described herein. Computer program 1310 and/or operating instructions may also be tangibly embodied in memory 1306 and/or data communications devices 1330, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 1302.

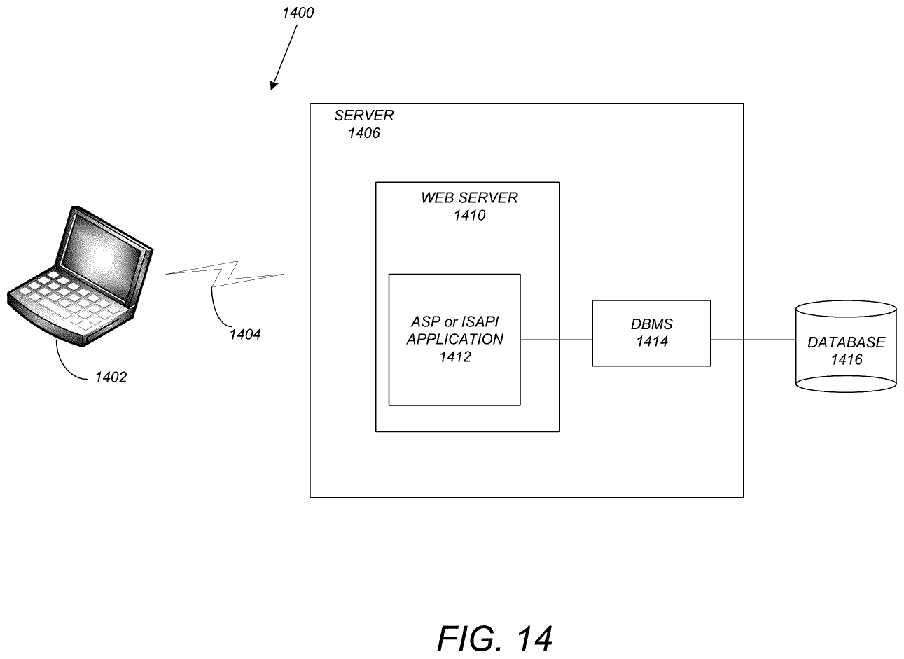

FIG. 14 schematically illustrates a typical distributed/cloud-based computer system 1400 using a network 1404 to connect client computers 1402 to server computers 1406. A typical combination of resources may include a network 1404 comprising the Internet, LANs (local area networks), WANs (wide area networks), SNA (systems network architecture) networks, or the like, clients 1402 that are personal computers or workstations (as set forth in FIG. 13), and servers 1406 that are personal computers, workstations, minicomputers, or mainframes (as set forth in FIG. 13). However, it may be noted that different networks such as a cellular network (e.g., GSM [global system for mobile communications] or otherwise), a satellite based network, or any other type of network may be used to connect clients 1402 and servers 1406 in accordance with embodiments of the invention.

A network 1404 such as the Internet connects clients 1402 to server computers 1406. Network 1404 may utilize ethernet, coaxial cable, wireless communications, radio frequency (RF), etc. to connect and provide the communication between clients 1402 and servers 1406. Further, in a cloud-based computing system, resources (e.g., storage, processors, applications, memory, infrastructure, etc.) in clients 1402 and server computers 1406 may be shared by clients 1402, server computers 1406, and users across one or more networks. Resources may be shared by multiple users and can be dynamically reallocated per demand. In this regard, cloud computing may be referred to as a model for enabling access to a shared pool of configurable computing resources.

Clients 1402 may execute a client application or web browser and communicate with server computers 1406 executing web servers 1410. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 1402 may be downloaded from server computer 1406 to client computers 1402 and installed as a plug-in or ACTIVEX control of a web browser. Accordingly, clients 1402 may utilize ACTIVEX components/component object model (COM) or distributed COM (DCOM) components to provide a user interface on a display of client 1402. The web server 1410 is typically a program such as MICROSOFT'S INTERNET INFORMATION SERVER.

Web server 1410 may host an Active Server Page (ASP) or Internet Server Application Programming Interface (ISAPI) application 1412, which may be executing scripts. The scripts invoke objects that execute business logic (referred to as business objects). The business objects then manipulate data in database 1416 through a database management system (DBMS) 1414. Alternatively, database 1416 may be part of, or connected directly to, client 1402 instead of communicating/obtaining the information from database 1416 across network 1404. When a developer encapsulates the business functionality into objects, the system may be referred to as a component object model (COM) system. Accordingly, the scripts executing on web server 1410 (and/or application 1412) invoke COM objects that implement the business logic. Further, server 1406 may utilize MICROSOFT'S TRANSACTION SERVER (MTS) to access required data stored in database 1416 via an interface such as ADO (Active Data Objects), OLE DB (Object Linking and Embedding DataBase), or ODBC (Open DataBase Connectivity).

Generally, these components 1400-1416 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 1402 and 1406 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 1402 and 1406. Embodiments of the invention are implemented as a software/CAD application on a client 1402 or server computer 1406. Further, as described above, the client 1402 or server computer 1406 may comprise a thin client device or a portable device that has a multi-touch-based display.

### CONCLUSION

This concludes the description of the preferred embodiment of the invention. The following describes some alternative embodiments for accomplishing the present invention. For example, any type of computer, such as a mainframe, minicomputer, or personal computer, or computer configuration, such as a timesharing mainframe, local area network, or standalone personal computer, could be used with the present invention.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A computer-implemented method for generating a stormwater overland flow map, comprising:
(a) obtaining simulation inputs and simulation outputs from a deluge simulation model, wherein:
(i) the deluge simulation model simulates where water will channel and accumulate on a surface;
(ii) the simulation inputs comprise ground surface data;
(iii) each simulation output comprises the stormwater overland flow map;
(b) training a convolutional neural network (CNN) to approximate the simulation outputs of the deluge simulation model, wherein:
(i) the CNN comprises a sequence of CNN models;
(ii) each CNN model in the sequence represents a time step;
(iii) a first CNN model in the sequence receives new ground image data and predicts the stormwater overland flow map for a subsequent time step;
(iv) each subsequent CNN model in the sequence takes CNN output from a previous CNN model as its CNN input;
(v) a CNN output comprises a video output that comprises a visual representation of stormwater overland flow over time;
(c) obtaining a new input comprising new ground surface data in a first format;
(d) storing, in memory, a collection of custom objects representing points of a grid, wherein each custom object comprises a first z-value of a point on the new ground surface data and a second z-value of a stormwater control on top of the new round surface data;
(e) populating the grid using the collection of custom objects; and
(f) processing the grid in the CNN to generate the CNN output.

2. The computer-implemented method of claim 1, wherein the CNN comprises a Bayesian CNN that estimates a map of standard deviations to address uncertainties in the deluge simulation model.

3. The computer-implemented method of claim 1, wherein the CNN is integrated with deep learning in real time to address uncertainties due to specific numerical methods utilized in the deluge simulation model.

4. The computer-implemented method of claim 1, wherein the CNN is processed in AMAZON WEB SERVICES using graphics processing unit (GPU) accelerated hardware.

5. The computer-implemented method of claim 1, wherein the grid comprises an ASCII (American Standard Code for Information Interchange) grid.

6. The computer-implemented method of claim 1, further comprising:
limiting a maximum level of water on a surface to be displayed in the CNN output.

7. The computer-implemented method of claim 6, further comprising:
the CNN output comprises bitmap coloring;
converting the bitmap coloring of the CNN output to depth data based on bitmap color values.

8. The computer-implemented method of claim 1, further comprising:
stamping a defined water collection area onto the new ground image data, wherein the stamping comprises interactively placing a polygonal shaped area onto the new ground image data;
repopulating the grid based on the defined water collection area; and
reprocessing the repopulated grid in the CNN to generate the CNN output, wherein the CNN output is generated and displayed in real time dynamically in response to the stamping.

9. The computer-implemented method of claim 8, wherein the stamping further comprises interactively moving the polygonal shaped area onto a different area of the new ground image data.

10. The computer-implemented method of claim 8, wherein the defined water collection area is selected from a group consisting of a pond, a swale, and a channel.

11. A computer-implemented system for generating a stormwater overland flow map, comprising:
(a) a computer having a memory;
(b) a processor executing on the computer;
(c) the memory storing a set of instructions, wherein the set of instructions, when executed by the processor cause the processor to perform operations comprising:
(i) obtaining simulation inputs and simulation outputs from a deluge simulation model, wherein:
(1) the deluge simulation model simulates where water will channel and accumulate on a surface;
(2) the simulation inputs comprise ground surface data;
(3) each simulation output comprises the stormwater overland flow map;
(ii) training a convolutional neural network (CNN) to approximate the simulation outputs of the deluge simulation model, wherein:
(1) the CNN comprises a sequence of CNN models;
(2) each CNN model in the sequence represents a time step;
(3) a first CNN model in the sequence receives new ground image data and predicts the stormwater overland flow map for a subsequent time step;
(4) each subsequent CNN model in the sequence takes CNN output from a previous CNN model as its CNN input;
(v) a CNN output comprises a video output that comprises a visual representation of stormwater overland flow over time;
(iii) obtaining a new input comprising new ground surface data in a first format;
(iv) storing, in memory, a collection of custom objects representing points of a grid, wherein each custom object comprises a first z-value of a point on the new ground surface data and a second z-value of a stormwater control on top of the new round surface data;
(v) populating the grid using the collection of custom objects; and
(vi) processing the grid in the CNN to generate the CNN output.

12. The computer-implemented system of claim 11, wherein the CNN comprises a Bayesian CNN that estimates a map of standard deviations to address uncertainties in the deluge simulation model.

13. The computer-implemented system of claim 11, wherein the CNN is integrated with deep learning in real time to address uncertainties due to specific numerical methods utilized in the deluge simulation model.

14. The computer-implemented system of claim 11, wherein the CNN is processed in AMAZON WEB SERVICES using graphics processing unit (GPU) accelerated hardware.

15. The computer-implemented system of claim 11, wherein the grid comprises an ASCII (American Standard Code for Information Interchange) grid.

16. The computer-implemented system of claim 11, further comprising:
limiting a maximum level of water on a surface to be displayed in the CNN output.

17. The computer-implemented system of claim 16, further comprising:
the CNN output comprises bitmap coloring;
converting the bitmap coloring of the CNN output to depth data based on bitmap color values.

18. The computer-implemented system of claim 11, further comprising:
stamping a defined water collection area onto the new ground image data, wherein the stamping comprises interactively placing a polygonal shaped area onto the new ground image data;
repopulating the grid based on the defined water collection area; and
reprocessing the repopulated grid in the CNN to generate the CNN output, wherein the CNN output is generated and displayed in real time dynamically in response to the stamping.

19. The computer-implemented system of claim 18, wherein the stamping further comprises interactively moving the polygonal shaped area onto a different area of the new ground image data.

20. The computer-implemented system of claim 18, wherein the defined water collection area is selected from a group consisting of a pond, a swale, and a channel.
